(19) United States
(12) Patent Application Publication
(10) Pub. No.: US 2018/0374166 A1
(43) Pub. Date: Dec. 27, 2018

(54) INFORMATION PROCESSING APPARATUS, INFORMATION PROCESSING METHOD THEREOF, AND PROGRAM

(71) Applicant: NEC Corporation, Minato-ku, Tokyo (JP)

(72) Inventor: Togo MURAKAMI, Tokyo (JP)

(73) Assignee: NEC Corporation, Minato-ku, Tokyo (JP)

(21) Appl. No.: 16/061,696

(22) PCT Filed: Oct. 6, 2016
(86) PCT No.: PCT/JP2016/079751

§ 371 Date: Jun. 13, 2018

(30) Foreign Application Priority Data
Dec. 14, 2015 (JP) 2015-243493

(51) Int. Cl. G06Q 50/06; G06Q 10/04; G01R 22/06; G01F 3/22

(52) U.S. Cl. CPC G06Q 50/06; G01F 3/22; G01R 22/061; G06Q 10/04

(57) ABSTRACT

An information processing apparatus includes a first-energy consumption acquisition unit that acquires a first energy consumption of a consumer, and a second-energy consumption estimation unit that estimates a second energy consumption of the consumer using the first energy consumption.

### TECHNICAL FIELD

The present invention relates to an information processing apparatus, an information processing method thereof, and a program, and particularly relates to an information processing apparatus for performing information processing relating to an energy consumption, an information processing method thereof, and a program.

### BACKGROUND ART

Patent Document 1 discloses an example of a delivery prediction system that collects indication data of a gas meter using a mobile terminal, and predicts a delivery day for the replacement of a gas container using the data.

In the system disclosed in Patent Document 1, the indication data includes a meter indication indicating the remaining amount of gas of the gas container and the meter-reading day. This system calculates gas usage from the previous meter-reading day to the current meter-reading day on the basis of the comparison of current indication data with previous indication data, and calculates the remaining amount of gas in the gas container on the basis of the gas usage, to thereby update a value of a storage unit.

Further, this system predicts the remaining amount of gas in the future by reducing the updated remaining amount of gas, in accordance with a prediction value of future gas usage per day which is predicted from the gas usage per day from the previous meter-reading day to the current meter-reading day, and determines a day on which the predicted remaining amount of gas becomes a predetermined value, as a delivery day of the gas container in supply facilities. In this system, the prediction value of the gas usage is predicted on the basis of the gas usage per day from the previous meter-reading day to the current meter-reading day, and the change rate of the gas usage per day in the past which is obtained based on indication data for the supply facilities during a predetermined past period.

Thereby, in the system disclosed in Patent Document 1, it is possible to stabilize supply of gas, to further reduce the remaining amount of gas that remains within a gas container brought back, and to achieve the efficiency of delivery of the gas container.

In addition, Patent Document 2 discloses an example of an abnormality determination method using data of usage of gas or water which is aggregated by a smart meter. In the abnormality determination method disclosed in Patent Document 2, the data of the usage of gas or water which is collected by the smart meter is transmitted to a center apparatus and accumulated in the center apparatus, an amount to be used in the future is estimated on the basis of the transition of the past usage accumulated, and whether being abnormal is determined on the basis of the estimated usage and the current usage.

### RELATED DOCUMENTS

### Patent Documents

[Patent Document 1] PCT International Publication No. WO 2013/183312

[Patent Document 2] Japanese Unexamined Patent Publication No. 2015-14562

### SUMMARY OF THE INVENTION

### Technical Problem

As disclosed in Patent Document 1, an LP gas company performs the replacement of the gas container of each household or building so that supply of gas is not interrupted. For example, generally, the gas usage per day is obtained by a conjecture based on an actual measurement value, the remaining amount of gas is predicted, a replacement timing of the gas container is determined, and a worker travels to the actual place at that timing to perform replacement work.

However, in a case where a determined replacement timing is late, and thus the actual remaining amount of gas is smaller than the remaining amount of gas predicted, it is likely that replacement does not make it on time. Further, in a case where the replacement timing is too early, the actual remaining amount of gas becomes larger than the remaining amount of gas predicted, and thus it is likely that the delivery cost of the gas container is wasted. In this manner, in the technique disclosed in the Patent Documents, since it is difficult to exactly predict the gas usage, there is a problem in that gas cannot be stably supplied.

The present invention is contrived in view of such circumstances, and an object thereof is to provide an information processing apparatus, an information processing method thereof, and a program which allows an energy consumption of a consumer to be efficiently and accurately conjectured.

### Solution to Problem

In each aspect of the present invention, each of the following configurations is adopted in order to solve the above-mentioned problem.

A first aspect relates to an information processing apparatus.

According to the first aspect, there is provided an information processing apparatus including: a first-energy consumption acquisition unit that acquires a first energy consumption of a consumer; and a second-energy consumption estimation unit that estimates a second energy consumption of the consumer, using the first energy consumption.

The second aspect relates to an information processing method which is executed by at least one computer.

According to the second aspect, there is provided an information processing method performed by an information processing apparatus, the method including: acquiring a first energy consumption of a consumer; and estimating a second energy consumption of the consumer, using the first energy consumption.

It should be noted that, in another aspect of the present invention, there may be provided a program causing at least one computer to execute the method according to the second aspect, and a computer readable storage medium having such a program recorded thereon. This storage medium includes a non-transitory tangible medium.

When such a computer program is executed by a computer, the computer program includes computer program codes causing the computer to carry out an information processing method thereof on an information processing apparatus.

It should be noted that any combination of the foregoing components, and those obtained by converting the representation of the present invention between a method, a device, a system, a storage medium, a computer program, and the like are also effective as aspects of the present invention.

In addition, various types of components of the present invention are not necessarily required to be present individually and independently, but a plurality of components may be formed as one member, one component may be formed by a plurality of members, a certain component may be a portion of another component, a portion of a certain component and a portion of another component may overlap each other, or the like.

In addition, a plurality of procedures are described in order in the method and the computer program of the present invention, but the order of the description is not intended to limit the order of the execution of the plurality of procedures. Therefore, when the method and the computer program of the present invention are executed, the order of the plurality of procedures may be changed within the range of not causing any problem in terms of the contents.

Further, the plurality of procedures of the method and the computer program of the present invention are not limited to be individually executed at timings different from each other. Therefore, a certain procedure may occur during the execution of another procedure, the run time of a certain procedure and a portion or the whole of the run time of another procedure may overlap, or the like.

### Advantageous Effects of Invention

According to each of the aspects, it is possible to provide an information processing apparatus, an information processing method thereof, and a program which are suitable for estimating the consumption of second energy different from first energy efficiently and accurately, on the basis of the consumption of the first energy.

### BRIEF DESCRIPTION OF THE DRAWINGS

The above and other objects, features and advantages will be made clearer from preferred example embodiments described below, and the following accompanying drawings.

FIG. 1 is a functional block diagram illustrating a logical configuration of an information processing apparatus according to an example embodiment of the present invention.

FIG. 2 is a diagram conceptually illustrating a system configuration of an information processing system including the information processing apparatus according to the example embodiment of the present invention.

FIG. 3 is a diagram illustrating an example of information stored in an information storage unit of the information processing apparatus of the present example embodiment.

FIG. 4 is a block diagram illustrating a configuration of a computer that realizes the information processing apparatus according to the example embodiment of the present invention.

FIG. 5 is a flow diagram illustrating an example of the operation of the information processing apparatus according to the example embodiment of the present invention.

FIG. 6 is a functional block diagram illustrating a logical configuration of an information processing apparatus according to an example embodiment of the present invention.

FIG. 7 is a diagram illustrating an example of a data structure of consumer gas information of the information processing apparatus of the present example embodiment.

FIG. 8 is a flow diagram illustrating an example of the operation of the information processing apparatus according to the example embodiment of the present invention.

FIG. 9 is a functional block diagram illustrating a logical configuration of an information processing apparatus according to an example embodiment of the present invention.

FIG. 10 is a diagram illustrating an example of a coefficient table of the information processing apparatus of the present example embodiment.

FIG. 11 is a diagram illustrating an example of a data structure of a user information storage unit of the information processing apparatus of the present example embodiment.

FIG. 12 is a diagram illustrating an example of a coefficient table of the information processing apparatus of the present example embodiment.

FIG. 13 is a diagram illustrating an example of a data structure of a facility information storage unit of the information processing apparatus of the present example embodiment.

FIG. 14 is a diagram illustrating an example of a coefficient table of the information processing apparatus of the present example embodiment.

FIG. 15 is a functional block diagram illustrating a logical configuration of an information processing apparatus according to an example embodiment of the present invention.

FIG. 16 is a diagram illustrating an example of a setting condition matrix table of a weighting coefficient w of a coefficient α of the information processing apparatus of the present example embodiment.

### DESCRIPTION OF EMBODIMENTS

Hereinafter, example embodiments of the present invention will be described with reference to the accompanying drawings. In all the drawings, like elements are referenced by like reference numerals and the descriptions thereof will not be repeated.

### First Example Embodiment

An information processing apparatus, an information processing method thereof, and a program according to a first example embodiment of the present invention will be described below.

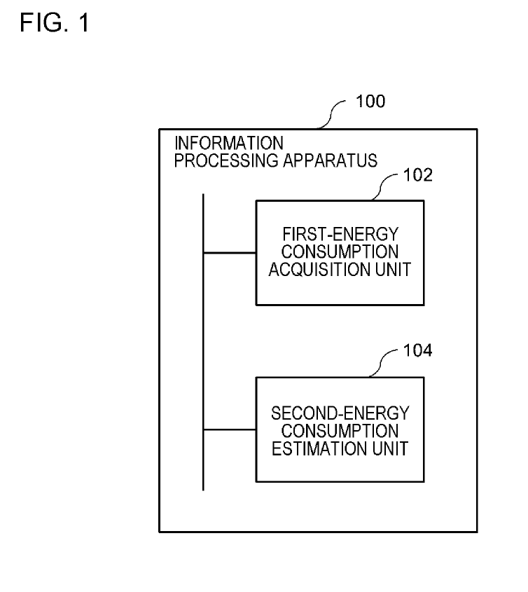

FIG. 1 is a functional block diagram illustrating a logical configuration of an information processing apparatus 100 according to the example embodiment of the present invention.

The information processing apparatus 100 of the present example embodiment includes a first-energy consumption acquisition unit 102 that acquires a first energy consumption of a consumer, and a second-energy consumption estimation unit 104 that estimates a second energy consumption of the consumer using the first energy consumption.

In each of the following drawings, the configurations of portions irrelevant to the essence of the present invention are omitted and not shown.

The first energy and the second energy are any of energies, such as, for example, power, gas, or kerosene, which are consumed by a consumer, and are energies different from each other. In the present example embodiment, the first energy is electric power, and the second energy is gas. The gas will be described by taking liquefied petroleum (LP) gas as an example, but city gas may not be excluded. In addition, in the present invention, the first energy and the second energy may be at least any one of electric power, gas and kerosene. In the present example embodiment, the first energy is electric power, and the second energy is gas, other than power. However, in another example, the first energy may be gas, and the second energy may be electric power. Alternatively, the first energy may be kerosene, and the second energy may be gas. In this manner, a combination of the first energy and the second energy is not particularly limited.

The first energy is energy of which an actual consumption in a consumer's home is measured, and the measurement value thereof is acquired by the information processing apparatus 100. On the other hand, the second energy refers to energy in which there is no means of the information processing apparatus 100 acquiring the measurement value of a consumption in a consumer's home, or the measurement value is not provided to the information processing apparatus 100.

In addition, the second energy also includes energy in which the accuracy of the measurement value is lower than a required level, or energy of which a consumption need be estimated because a timing at which the measurement value can be acquired does not match a timing at which the measurement value is used, or the like. Consequently, in the present invention, the second energy consumption is estimated using the first energy consumption.

There is a correlation between the first energy consumption and the second energy consumption. The second-energy consumption estimation unit 104 estimates the second energy consumption from the first energy consumption, on the basis of this correlation.

The correlation changes depending on the conditions such as the attribute (for example, a region or a configuration of facilities or devices using each energy) of a consumer's residence (building), the make-up of a family living in the residence, the use time or use details of a building, the season, the rate of each energy, and the like. A specific processing method according to various conditions will be described in example embodiments described later.

In the present specification, the term “acquisition” includes at least any one of causing the own apparatus to fetch data or information stored in another apparatus or a storage medium (active acquisition) such as, for example, receiving the data or information by sending a request or a query to another apparatus or reading out the data or information by accessing another apparatus or a storage medium, and inputting data or information, output from another apparatus, to the own apparatus (passive acquisition) such as, for example, receiving data or information to be delivered (transmitted, pushed or the like). In addition, the acquisition also includes performing selection and acquisition from the received data or information, or selecting and receiving the delivered data or information.

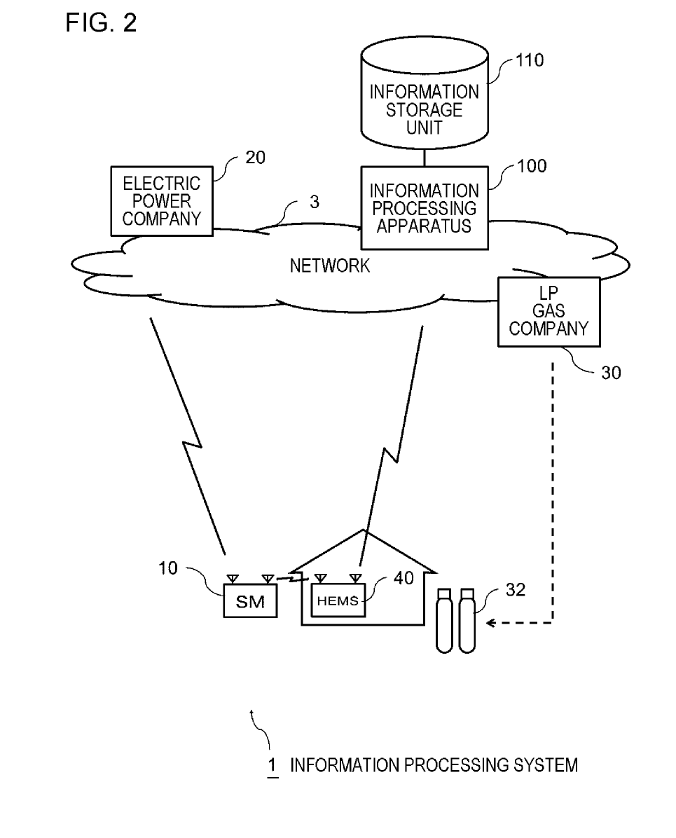

FIG. 2 is a diagram conceptually illustrating a system configuration of an information processing system 1 including the information processing apparatus 100 according to the example embodiment of the present invention.

In the present example embodiment, the information processing system 1 includes the information processing apparatus 100 that acquires information relating to the electric power consumption from a consumer, predicts the gas usage by a consumer, and provides the amount to an LP gas company 30.

An information storage unit 110 is connected to the information processing apparatus 100. The information storage unit 110 may be included inside the information storage unit 110, and may be provided outside the information processing apparatus 100 so that the information processing apparatus 100 can have access thereto.

For example, information of the first energy consumption of a consumer acquired by the first-energy consumption acquisition unit 102 and information of the second energy consumption of a consumer estimated by the second-energy consumption estimation unit 104 are stored in the information storage unit 110. Further, various types of information (such as, for example, a consumer's information and information relating to the weather) used when the second-energy consumption estimation unit 104 performs an estimation process may be stored in the information storage unit 110.

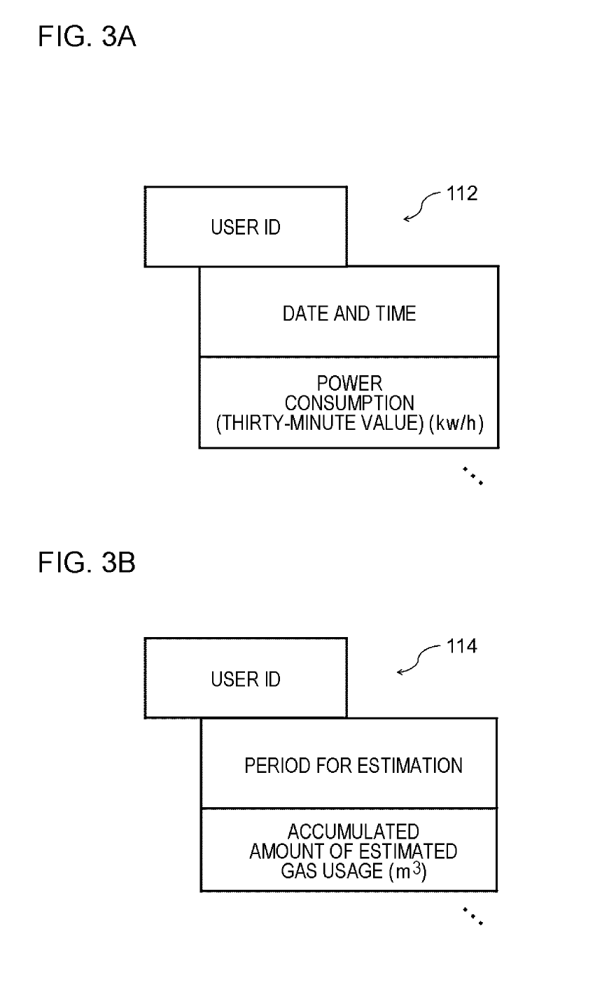

FIG. 3 is a diagram illustrating an example of information stored in the information storage unit 110 of the information processing apparatus 100 of the present example embodiment.

FIG. 3A shows an example of a data structure of the information of the first energy consumption of a consumer. In the present example embodiment, the first energy is electric power, and the first energy consumption is information relating to the electric power consumption which is acquired by the first-energy consumption acquisition unit 102. Electric power consumption information 112 of FIG. 3A has the electric power consumption of a consumer (such as, for example, a thirty-minute value) associated with date and time information.

In the present example embodiment, the information relating to the electric power consumption which is acquired by the first-energy consumption acquisition unit 102 is a thirty-minute value, and the acquired information (thirty-minute value) relating to the electric power consumption is stored in the information storage unit 110 for each consumer. For example, as shown in FIG. 3A, the thirty-minute value of the electric power consumption is stored in the information storage unit 110 as the electric power consumption information 112 of a consumer, for each consumer's user ID, in association with the measurement date and time information. The thirty-minute value of the electric power consumption indicates the amount of power consumed for 30 minutes.

A description for a configuration of the electric power consumption information 112 has been given in which every “thirty-minute value” of the power consumption is stored whenever being acquired, but there is no limitation thereto. Values obtained by integrating the thirty-minute value every predetermined period such as every hour may be stored in the information storage unit 110 as the electric power consumption information 112. A plurality of values, for example, any of a thirty-minute value, an hour's integration value, a day's integration value, and the like may be stored in the information storage unit 110 as the electric power consumption information 112.

FIG. 3B shows an example of a data structure of the information of the second energy consumption of the present example embodiment. In the present example embodiment, the second energy is gas, and the second energy consumption is information relating to the gas usage by a consumer estimated by the second-energy consumption estimation unit 104. Estimated-gas-usage information 114 of FIG. 3B has the estimated total gas usage of a consumer during a predetermined period for estimation associated with information of the period for estimation.

The period for estimation indicates, for example, a period from a time at which a gas cylinder 32 is last replaced to a timing (based on date and time information of the electric power consumption which is used in estimation) at which the estimation process is performed. Specifically, the period for estimation may include start date and time information of the period for estimation and end date and time information thereof, and may include the start date and time information and information of the number of days indicating a period.

The information relating to the gas usage which is estimated by the second-energy consumption estimation unit 104 is a value obtained by totalizing during the period for estimation gas usage estimated from the electric power consumption, and is stored in the information storage unit 110 for each consumer. For example, as shown in FIG. 3B, the total value of the estimated gas usage is stored in the information storage unit 110, for each consumer's user ID, as the estimated-gas-usage information 114 of a consumer in association with the information of the period for estimation.

For example, the second-energy consumption estimation unit 104 estimates the second energy consumption (the gas usage) whenever the first energy consumption (the electric power consumption) is acquired from a smart meter 10.

As an example, by using the thirty-minute value of the electric power consumption of a consumer, the estimated gas usage for every thirty minutes corresponding to the electric power consumption is calculated. The estimated gas usage for thirty minutes is totalized during the period for estimation, and the accumulated amount of estimated gas usage is calculated.

As another example, the second-energy consumption estimation unit 104 estimates the second energy consumption (the gas usage) on the basis of the integration value of the first energy consumption (the electric power consumption) which is acquired from the smart meter 10.

As an example, the thirty-minute value of the electric power consumption is totalized during the period for estimation to obtain the integration value. The estimated gas usage during the period for estimation may be calculated using a time-series variation (for example, every thirty minutes) in the adjusted power consumption.

Further, the period for estimation may be divided for each predetermined time slot and the thirty-minute value of the electric power consumption may be totalized for each time slot, and the estimated total gas usage in a corresponding time slot may be calculated using the value.

The second-energy consumption estimation unit 104 calculates an estimation value on the basis of the electric power consumption of a consumer, and stores the calculated estimation value in the information storage unit 110, but a unit of calculation and a unit of storage are considered in various ways. For example, in a case where the power consumption as a basis is a thirty-minute value, the gas usage may be estimated in the same unit (for example, thirty-minute value) as that of the electric power consumption, and each value may be stored.

Alternatively, in a case where the electric power consumption as a basis is a thirty-minute value, a value obtained by collecting the electric power consumption over a predetermined period, for example, a day's worth of integration value is obtained. The gas usage for a day may be estimated on the basis of a time-series variation in the value of the electric power consumption (every thirty minutes) integrated over a day, and a value in the unit of a day may be stored. For example, the gas usage for a day may be obtained by representing the time-series variation in the electric power consumption by a gradient (differential) per unit time, estimating from the gradient the time-series variation in the gas usage, and integrating the estimated value, which is per unit time, for a day. In addition, electric power consumption as a basis, the integration value may be used, rather than the thirty-minute value.

In this manner, the unit of the estimated gas usage and the unit of the electric power consumption may be the same as each other, and may be different from each other.

In addition, the estimated-gas-usage information 114 may calculate a plurality of values, for example, any of a thirty-minute value, an hour's total value, a day's total value, ten days' total value, and the like, and may store each of the values.

In the example of FIG. 3B, the total value of the gas usage from after the replacement of the gas cylinder 32 is stored, but in another example, the remaining amount of gas of the gas cylinder 32 may be stored. The remaining amount of gas may be obtained by subtracting the estimated gas usage from the capacity of a container (gas cylinder 32). As to the total value or the remaining amount of gas, up-to-date information at the time of calculation may be stored, or every calculated value may be stored in association with the date and time information whenever the value is calculated.

Referring back to FIG. 2, the smart meter 10 supplied from an electric power company 20 to a consumer is installed in a consumer's home. The smart meter 10 is an electric energy meter having a communication function. The electric energy meter measures the consumption of power supplied to a consumer's home. Power is supplied from the electric power company 20 or an electric power retailer (not shown) through a power transmission and distribution network (not shown) to a consumer's home. In addition, the power transmission and distribution network is managed by a power transmission and distribution provider (not shown).

Information of the electric power consumption or the like measured by the smart meter 10 is transmitted periodically (for example, every thirty minutes) from the smart meter 10 through a so-called route A to the electric power company 20 on a network 3.

A communication system of the route A between the smart meter 10 and the electric power company 20 is not particularly limited, and may have a wireless communication system such as, for example, worldwide interoperability for microwave access (WiMAX), 3rd generation (3G), or long term evolution (LTE) used therein.

In addition, in a consumer's home, LP gas is used, and the LP gas company 30 periodically performs replacement work of the gas cylinder 32 in the consumer's home. Generally, the LP gas company 30 periodically travels to a consumer's home, and ascertains the remaining amount of the gas cylinder 32 to perform its replacement work. In a case where its replacement timing is too late, the supply of gas is interrupted, and thus there is a problem in that a user is not able to use gas. Reversely, in a case where its replacement timing is too early, there is a problem in that the delivery cost of the gas cylinder 32 is wasted. For example, two gas cylinders 32 are disposed at every consumer's home, and are used in order one by one. In a case where the remaining amount of a first one becomes less than a predetermined value, switching to the other one is performed manually or automatically.

In the present example embodiment, the electric power company 20 and the LP gas company 30 are assumed to be operated by one company or the same management system. The information processing apparatus 100 may be connected to a server (not shown) managed by at least one of the electric power company 20 and the LP gas company 30 through the network 3. Alternatively, the information processing apparatus 100 may be included in the server of at least one of the electric power company 20 and the LP gas company 30.

Further, in another example embodiment, in a case where the electric power company 20 and the LP gas company 30 are companies different from each other, the information processing apparatus 100 may be connected to the server of the electric power company 20 or the LP gas company 30 or a server of another service provider (not shown) through a network, and may be included in any of the servers.

The network 3 of FIG. 2 is a network such as a public network, a LAN, a wide area network (WAN), a metropolitan area network (MAN), or a wireless MAN.

In addition, for example, a home energy management system (HEMS) 40 is included in a consumer's home, communicates with the smart meter 10 through a so-called route B, and receives the electric power consumption which is measured by the smart meter 10.

A communication method in the route B between the smart meter 10 and the HEMS 40 is not particularly limited, and for example, a specific small-power wireless system using a band of 920 MHz, for example, a communication system based on a communication standard such as WiSUN, or a communication system of a wireless communication standard operating on IEEE802.15.4 such as Zigbee (Registered Trademark) may be used.

Further, the HEMS 40 may transmit the electric power consumption, which is received from the smart meter 10, to the information processing apparatus 100 through a so-called route C.

A communication system between the HEMS 40 and the information processing apparatus 100 is not particularly limited. As the communication system, for example, a wireless communication system such as worldwide interoperability for microwave access (WiMAX), 3G, or LTE may be used, and a wireless local area network (LAN) communication system such as a wired local area network (LAN) or Wi-Fi may be used. Either wired communication or wireless communication may be used between the HEMS 40 and the information processing apparatus 100.

In such a system configuration, the transmission of the electric power consumption of a consumer from the smart meter 10 to the information processing apparatus 100 may be performed through at least any of the following paths.

(a1) The electric power consumption is transmitted from the smart meter 10 through the HEMS 40 to the information processing apparatus 100.

(a2) The electric power consumption is transmitted from the smart meter 10 to the server of at least one of the electric power company 20 and the LP gas company 30, and is further transmitted from the server of at least one of the electric power company 20 and the LP gas company 30 to the information processing apparatus 100.

In a case where the electric power company 20 and the LP gas company 30 are separate companies, a service provider (such as the LP gas company 30 or a service provider) obtains a consumer's consent, as necessary, with respect to the acquisition of information relating to the past electric power consumption of a consumer from the electric power company 20 or a power transmission and distribution provider. The timing may be any time before information acquisition starts, and a consent method is also not particularly limited.

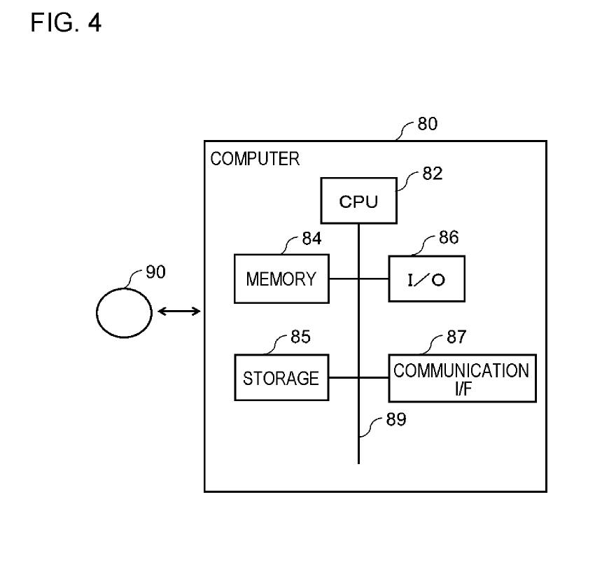

FIG. 4 is a diagram illustrating an example of a configuration of a computer 80 that realizes the information processing apparatus 100 of the present example embodiment.

The computer 80 of the present example embodiment includes a central processing unit (CPU) 82, a memory 84, a program 90, loaded into the memory 84, for realizing the components of FIG. 2, a storage 85 that stores the program 90, an input/output (I/O) 86, and a network connection interface (communication I/F 87).

The CPU 82, the memory 84, the storage 85, the I/O 86, and the communication I/F 87 are connected to each other through a bus 89, and the entire information processing apparatus 100 is controlled by the CPU 82. However, a method of connecting the CPU 82 and the like to each other is not limited to bus connection.

The memory 84 is a memory such as a random access memory (RAM) or a read only memory (ROM). The storage 85 is a storage apparatus such as a hard disk, a solid state drive (SSD), or a memory card.

The storage 85 may be a memory such as a RAM or a ROM. The storage 85 may be provided inside the computer 80, may be provided outside the computer 80 in a case where the computer 80 can have access thereto, and may be connected to the computer 80 in a wired or wireless manner. Alternatively, the storage may be provided in a demountable manner from the computer 80.

Each function of each unit of the information processing apparatus 100 in FIG. 1 can be realized by the CPU 82 reading out the program 90 stored in the storage 85 into the memory 84 and executing the read-out program.

The I/O 86 performs input and output control of data and control signals between the computer 80 and other input and output apparatuses. Examples of other input and output apparatuses include input apparatuses (not shown) such as a keyboard, a touch panel, a mouse, and a microphone which are connected to the computer 80, output apparatuses (not shown) such as a display, a printer, and a speaker, and interfaces between these input and output apparatuses and the computer 80. Further, the I/O 86 may perform control of input and output of data to and from reading or writing apparatuses (not shown) of other storage mediums.

The communication I/F 87 is a network connection interface for performing communication between the computer 80 and an external apparatus. The communication I/F 87 may be a network interface for connection to a wire circuit, and may be a network interface for connection to a wireless circuit. For example, the computer 80 that realizes the information processing apparatus 100 is connected to the HEMS 40 through the network 3 by the communication I/F 87.

Each component of the information processing apparatus 100 of the present example embodiment of FIG. 1 is realized by any combination of hardware and software of the computer 80 of FIG. 4. It will be understood by those skilled in the art that realizing methods and apparatuses thereof may be modified in various ways. A functional block diagram illustrating an information processing apparatus of each example embodiment which will be described below shows a block of a logical functional unit rather than a configuration of a hardware unit.

The information processing apparatus 100 may be constituted by a plurality of computers 80, and may be realized by a virtual server. In the present example embodiment, the information processing apparatus 100 is described as, for example, a server apparatus of a service provider different from the electric power company 20 and the LP gas company 30. As another example, the information processing apparatus 100 may be realized by the server apparatus of the electric power company 20 or the LP gas company 30. Alternatively, the information processing apparatus 100 may be realized by a server apparatus of an electric power retailer, an aggregator or the like.

The computer program 90 of the present example embodiment is described so as to cause the computer 80 for realizing the information processing apparatus 100 to execute a procedure of acquiring the first energy consumption of a consumer, and a procedure of estimating the second energy consumption of a consumer using the first energy consumption.

The computer program 90 of the present example embodiment may be stored in a storage medium readable by the computer 80. The storage medium is considered to have various forms without being particularly limited. In addition, the program 90 may be loaded from the storage medium into the memory 84 of the computer 80, and may be downloaded in the computer 80 through a network and be loaded into the memory 84.

The storage medium having the computer program 90 stored therein includes a medium capable of being used by the non-transitory tangible computer 80, and has program codes readable by the computer 80 embedded in the medium. When the computer program 90 is executed on the computer 80, the computer 80 is caused to execute an information processing method, described later, for realizing the information processing apparatus 100.

An information processing method of the information processing apparatus 100 of the present example embodiment configured in this manner will be described below.

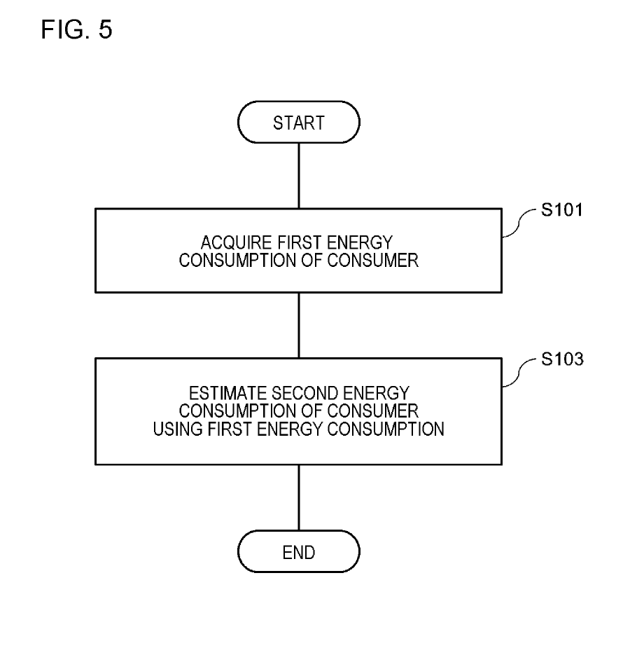

FIG. 5 is a flow diagram illustrating an example of the operation of the information processing apparatus 100 of the present example embodiment.

The information processing method according to the example embodiment of the present invention is an information processing method of the information processing apparatus 100, and is an information processing method executed by the computer 80 that realizes the information processing apparatus 100.

The information processing method of the present example embodiment includes causing the information processing apparatus 100 to acquire the first energy consumption of a consumer (step S101), and to estimate the second energy consumption of a consumer using the first energy consumption (step S103).

Specifically, first, in a consumer's home, the smart meter 10 measures the electric power consumption of a consumer, and transmits the measured electric power consumption to the HEMS 40. The first-energy consumption acquisition unit 102 receives the measurement value of the electric power consumption of a consumer from the HEMS 40 through the network 3 (step S101). A timing at which the first-energy consumption acquisition unit 102 receives the electric power consumption is not particularly limited. The acquisition unit may acquire information relating to the electric power consumption during at least a period between after the gas cylinder 32 is replaced and before the remaining amount of the gas cylinder 32 becomes less than a predetermined value.

The information relating to the electric power consumption of a consumer acquired by the first-energy consumption acquisition unit 102 is stored in the information storage unit 110 of FIG. 3A, for each consumer, as the electric power consumption information 112.

The second-energy consumption estimation unit 104 refers to the electric power consumption information 112 of a consumer of the information storage unit 110, and estimates the gas usage of a consumer for a predetermined period from the integration value of the electric power consumption of a consumer for a predetermined period (step S103). The estimated gas usage is stored in the information storage unit 110, for each consumer, as the estimated-gas-usage information 114.

For example, as shown in FIG. 3B, the estimated total gas usage which is obtained by totalizing the estimated gas usage of a consumer during a period for estimation is stored in the information storage unit 110 as the estimated-gas-usage information 114 of a consumer, in association with information of the period for estimation.

Since the total gas usage of a consumer is obtained in this manner, a time to replace the gas cylinder 32 can be predicted on the basis of information such as the capacity of the gas cylinder 32. For example, the information processing apparatus 100 may further include a notification unit (not shown) that notifies, in a case where the calculated remaining amount of gas becomes less than a predetermined value, the LP gas company 30 to that effect. According to this configuration, it is possible to notify the LP gas company 30 of a time to replace the gas cylinder 32 of a consumer.

As described above, in the information processing apparatus 100 of the present example embodiment, the second energy consumption, for example, the gas usage is estimated by the second-energy consumption estimation unit 104 on the basis of the first energy consumption, for example, the electric power consumption, which is acquired by the first-energy consumption acquisition unit 102.

In this manner, according to the information processing apparatus 100 of the present example embodiment, since meter-reading data of an electric energy meter that measures the first energy (electric power) consumption is used, the second energy (gas) consumption can be estimated even in a case where an apparatus that measures the second energy (gas) consumption is not provided. Thereby, a time to replace the gas cylinder 32 can be predicted on the basis of the capacity of the gas cylinder 32 and last replacement date and time information.

In addition, in a case of the estimation of the gas usage based on the gas usage in the past, changes between the past situation of utilization and the current situation of utilization due to a change in a consumer's lifestyle, abnormal weather, and a change in other social conditions, or the like make it difficult to perform exact prediction. However, in the information processing apparatus 100 of the present example embodiment, even in a case where there are changes between the past situation of utilization and the current situation of utilization, the second energy (gas) consumption can be estimated by the first energy (power) consumption changing along the current real situation, on the basis of a correlation between the electric power consumption and the gas usage, and thus it is possible to perform accurate prediction.

In this manner, since the accuracy of prediction of the gas usage improves, a shortage of the remaining amount of gas is prevented, and thus it is possible to stably supply gas, and to eliminate a waste of the delivery cost of the gas cylinder 32.

### Second Example Embodiment

Next, an information processing apparatus 130 according to a second example embodiment of the present invention will be described below.

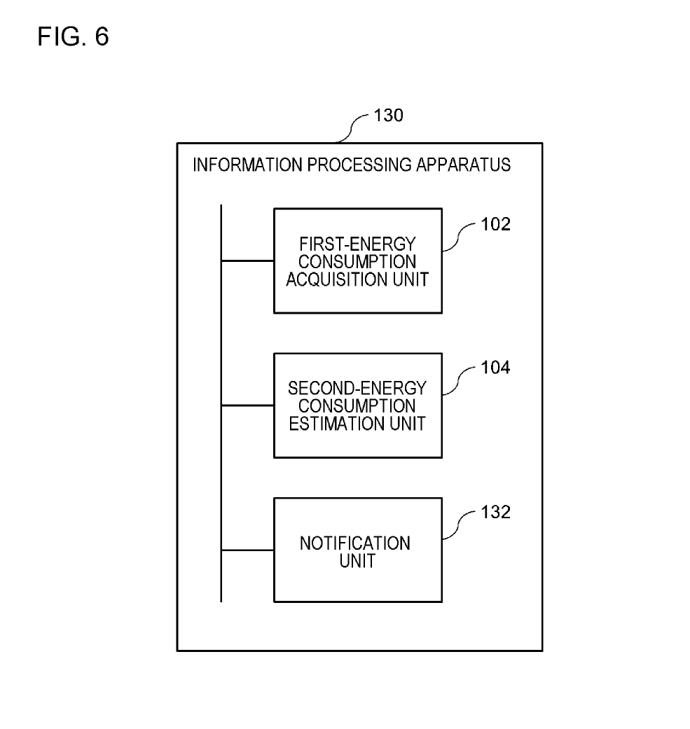

FIG. 6 is a functional block diagram illustrating a logical configuration of the information processing apparatus 130 according to the second example embodiment of the present invention.

The information processing apparatus 130 of the present example embodiment includes the first-energy consumption acquisition unit 102, the second-energy consumption estimation unit 104, and a notification unit 132. The first-energy consumption acquisition unit 102 and the second-energy consumption estimation unit 104 are the same as those of the information processing apparatus 100 of the example embodiment of FIG. 1.

Note that the notification unit 132 of the present example embodiment may also be combined with configurations of information processing apparatuses of other example embodiments described later.

The notification unit 132 calculates, for example, the remaining amount of the gas cylinder 32 from the second energy consumption (the gas usage) which is estimated by the second-energy consumption estimation unit 104, and gives notice of the replacement of the gas cylinder 32.

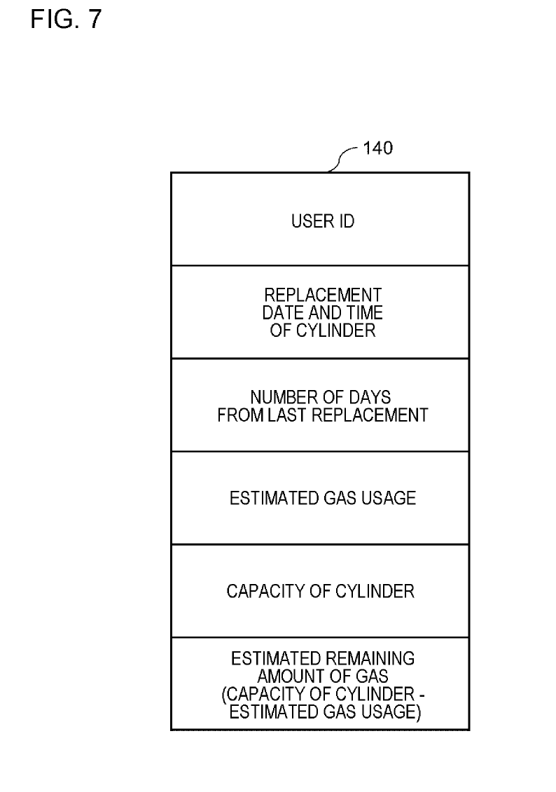

FIG. 7 is a diagram illustrating an example of a data structure of consumer gas information 140 of the information processing apparatus 130 of the present example embodiment.

The consumer gas information 140 stores the replacement date and time of the gas cylinder 32, the number of days elapsed after the gas cylinder 32 is last replaced, the gas usage which is estimated by the second-energy consumption estimation unit 104, and the capacity of the gas cylinder 32, in association with a consumer's user ID.

The second-energy consumption estimation unit 104 reads out information of the capacity of the gas cylinder 32 and the estimated gas usage from the consumer gas information 140, calculates the remaining amount of the gas cylinder 32, and stores the calculated remaining amount in the consumer gas information 140.

The notification unit 132 notifies the server of the LP gas company 30 of a time to replace the gas cylinder 32, for example, in a case where a predetermined ratio (for example, 5%) of the capacity of the gas cylinder 32 is set to a threshold, and the calculated remaining amount of the gas cylinder 32 becomes less than the threshold. In addition, a notification destination is not limited to the LP gas company 30, and a consumer may be notified of the time. In addition, a determination may be made based on the gas usage instead of a determination based on the remaining amount of gas. That is, in a case where the estimated gas usage becomes equal to or greater than a predetermined value, notice of a time to replace the gas cylinder 32 may be given. The predetermined value of the gas usage may be set to a predetermined ratio of the capacity of gas cylinder 32, for example, 95%.

It takes a certain number of days until notice of the replacement of the gas cylinder 32 is given, and then replacement work of the gas cylinder 32 is actually performed. Therefore, it is likely that giving a notice of the replacement of the gas cylinder 32 after the remaining amount of gas of the gas cylinder 32 becomes almost empty cannot allow replacement work to be in time. Consequently, in the present example embodiment, a predetermined value for determination (predetermined ratio) is set so that the amount of gas predicted to be used for the number of days necessary for the replacement work can be ensured within the gas cylinder 32.

A notification method is considered in various ways, and a notification may be performed through mail transmission, other electronic message delivery, display on a predetermined web page (such as a consumer's personalized page), or the like. Information may be transmitted to the HEMS 40 of a consumer and be displayed on the operating panel of the HEMS 40, a light emitting diode (LED) indicator or the like to notify a consumer of the information. In a case where a consumer is notified of the information, the consumer may inform the LP gas company 30 of a request for replacement work of the gas cylinder 32 through mail, a telephone, application from a web page, or the like.

Further, the notification unit 132 may give notice of a time to replace the container (gas cylinder 32), the time being set on the basis of a history of the second energy consumption (the gas usage) estimated by the second-energy consumption estimation unit 104 and the capacity of the container (gas cylinder 32) that contains the second energy (gas).

For example, a recommended replacement deadline can be obtained from the last replacement day of the gas cylinder 32 (that is, start day of use of the gas cylinder 32), the capacity of the gas cylinder 32, and a history of the specified gas usage. As the replacement day, a record of the date and time when replacement is actually performed by a worker may be used.

Notification contents are not particularly limited, and include at least any one of the remaining amount of the gas cylinder 32 becoming less than a threshold, an approximation of the estimated gas usage getting closer to the capacity of the gas cylinder 32, a time to replace the gas cylinder 32 approaching, an estimation value of the remaining amount, the number of days remaining until the gas cylinder 32 becomes empty, a recommended replacement deadline, and the like.

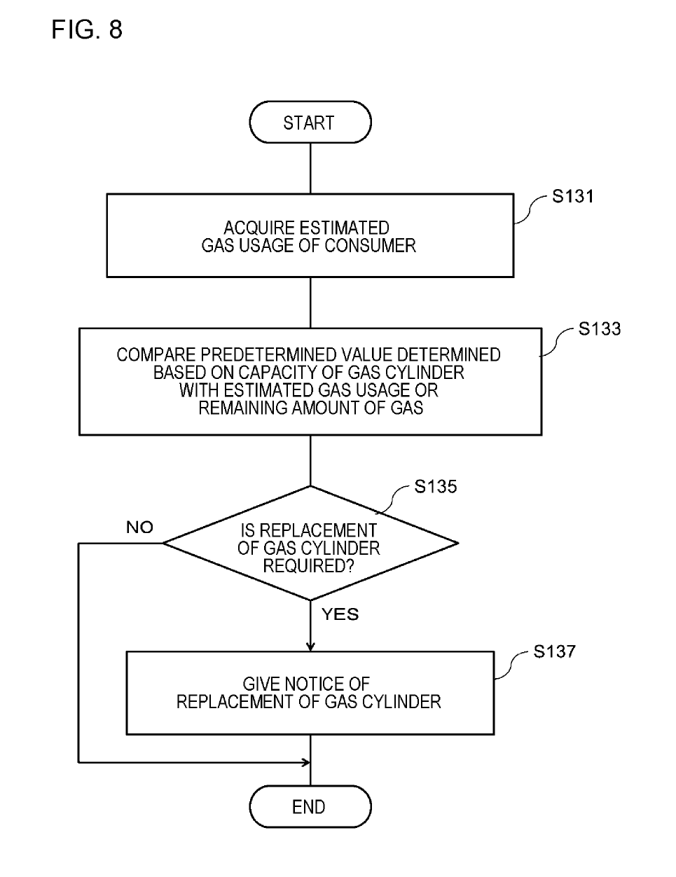

FIG. 8 is a flow diagram illustrating an example of the operation of the information processing apparatus 130 of the present example embodiment.

First, the notification unit 132 acquires the estimated gas usage of a consumer from the second-energy consumption estimation unit 104 (step S131). The notification unit 132 compares a predetermined value determined on the basis of the capacity of the gas cylinder 32 with the estimated gas usage or the remaining amount of gas. Determination processes are different from each other as follows, depending on which value is used for the comparison.

<Determination Process Using Estimated Gas Usage>

In a case where the estimated gas usage is used, a predetermined ratio (for example, 95%) of the capacity of the gas cylinder 32 is set to a predetermined value. When the estimated gas usage becomes equal to or less than the predetermined value, the notification unit 132 determines that the replacement of the gas cylinder 32 is required (YES in step S135). The notification unit 132 then gives notice of the replacement of the gas cylinder 32 (step S137). On the other hand, when the estimated gas usage is less than the predetermined value, the notification unit 132 determines that the replacement of the gas cylinder 32 is not yet required (NO in step S135), and the present process is terminated.

<Determination Process Using Remaining Amount of Gas>

In a case where the remaining amount of gas is used, a predetermined ratio (for example, 5%) of the capacity of the gas cylinder 32 is set to a predetermined value. When the remaining amount of gas becomes less than the predetermined value, the notification unit 132 determines that the replacement of the gas cylinder 32 is required (YES in step S135). The notification unit 132 then gives notice of the replacement of the gas cylinder 32 (step S137). On the other hand, when the remaining amount of gas is equal to or greater than the predetermined value, the notification unit 132 determines that the replacement of the gas cylinder 32 is not yet required (NO in step S135), and the present process is terminated.

According to this configuration, the gas usage is estimated on the basis of the electric power consumption which is measured by the smart meter 10, and the remaining amount of the gas cylinder 32 can be further estimated. When the remaining amount of the gas cylinder 32 becomes less than a threshold, or when the estimated gas usage becomes equal to or greater than the predetermined value, notice of the replacement of the gas cylinder 32 can be given, and thus it is possible to replace the gas cylinder 32 at an appropriate timing. Thereby, it is possible to achieve the stable supply of gas and a reduction in the delivery cost.

### Third Example Embodiment

Next, an information processing apparatus 200 according to a third example embodiment of the present invention will be described below.

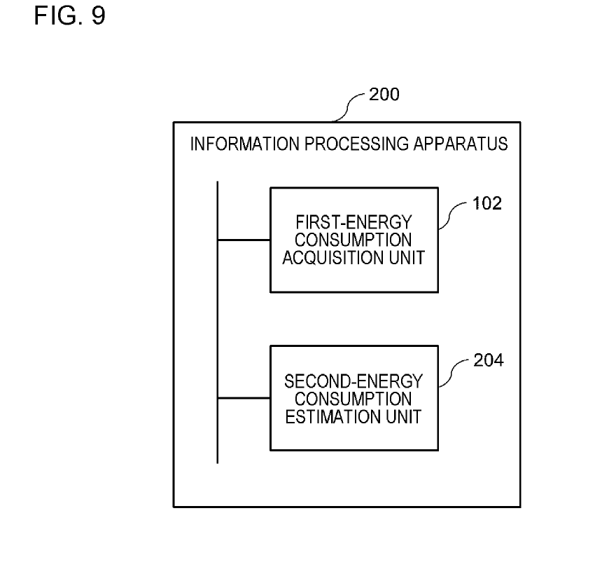

FIG. 9 is a functional block diagram illustrating a logical configuration of the information processing apparatus 200 according to the example embodiment of the present invention.

The information processing apparatus 200 of the present example embodiment is different from those of the above example embodiments, in that the second-energy consumption estimation unit includes a configuration in which the second energy consumption is estimated using another information, for example, information relating to the weather, in addition to the information of the first energy consumption of a consumer.

The information processing apparatus 200 of the present example embodiment includes the first-energy consumption acquisition unit 102 and a second-energy consumption estimation unit 204. In the present example embodiment, the first-energy consumption acquisition unit 102 is the same as that of the information processing apparatus 100 in FIG. 1 or that of the information processing apparatus 130 in FIG. 6 of the above example embodiments.

The second-energy consumption estimation unit 204 estimates the second energy consumption of a consumer using the first energy consumption, and further changes a coefficient indicating a correlation between the first energy consumption and the second energy consumption, on the basis of information relating to the weather.

Specifically, the second-energy consumption estimation unit 204 acquires an accumulated value of the first energy consumption consumed over a predetermined period, and calculates the second energy consumption for the predetermined period, in accordance with the following Expression (1), on the basis of the acquired accumulated first energy consumption.

Second energy consumption=accumulated first energy consumption×α×β Expression (1)

In Expression (1), α is a coefficient indicating a correlation between the first energy (power) and the second energy (gas), and β is a coefficient based on the information relating to the weather.

In the present example embodiment, the first energy is electric power, and the second energy is gas. In this case, the coefficient α also serves as a conversion coefficient for converting a unit (for example, kW/h) indicating the electric power consumption into a unit (for example, m³) indicating the gas usage. In another form, for example, in a case where the second energy is kerosene, the coefficient α may also serve as a conversion coefficient for converting a unit (kW/h) indicating the electric power consumption into a unit (for example, liter) indicating a kerosene consumption. In this manner, the coefficient α may also serve as a conversion coefficient for converting units according to the first energy and the second energy.

The information relating to the weather indicates weather conditions on a certain date and time in a place where a consumer's building is located. For example, the information includes the state of the atmosphere obtained by integrating atmospheric pressure, air temperature, humidity, wind direction, wind speed, the amount of cloud, the amount of rainfall, and the like. Particularly, since air temperature, humidity, the amount of rainfall, and the like are relevant to energy consumption, it is preferable that the information relating to the weather includes at least any one of pieces of information of air temperature, humidity, and the amount of rainfall. Alternatively, pieces of information of the season, the date and time, the time slot, and the like may be included therein.

Here, since the information relating to the weather is also highly relevant to a region, information relating to a region as well as weather information may be used as the information relating to the weather. For example, Hokkaido, Tohoku, and Hokuriku District may be set to cool regions, Kanto, Kinki, Shikoku, and Chugoku District may be set to warm-temperature regions, and Okinawa and Kyushu Region may be set to semitropical regions.

The present invention is characterized by a way to determine the coefficient α in Expression (1). A way to determine the coefficient α will be described below in detail. At least any of or a plurality of methods described below may be combined.

<Change Based on Consumption Pattern>

The second-energy consumption estimation unit 204 changes the coefficient α on the basis of the consumption pattern of the first energy.

In the present example embodiment, the consumption pattern of the first energy indicates, for example, the transition of the electric power consumption of a consumer by the time, the time slot, the month, the season, and the like.

The second-energy consumption estimation unit 204 can obtain a consumer's consumption pattern of the first energy on the basis of the first energy consumption of the consumer collected by the first-energy consumption acquisition unit 102.

A method of matching a group's consumption pattern with a consumer's consumption pattern is considered in various ways, and is not particularly limited. The degree of similarity in graphic shape between each consumption pattern and a consumer may be calculated by pattern matching, and it may be determined that the consumer belongs to a group having a degree of similarity equal to or greater than a predetermined value. Alternatively, a change (for example, derivative value) of a difference in power consumption between a group and a consumer for each time slot may be calculated, and it may be determined that the consumer belongs to a group in which the change in difference is less than the predetermined value.

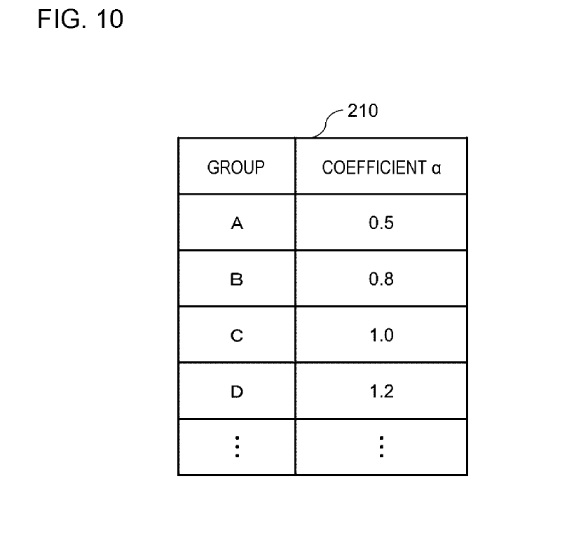

The consumption patterns of the first energy and the second energy are substantially determined by a consumer's lifestyle (attributes such as the make-up of a family or a facility of a building). In the present example embodiment, groups are set according to the consumption pattern of the first energy, and the coefficient α is set for each group. The set coefficient α is stored in a coefficient table 210 of FIG. 10 in association with a group.

The second-energy consumption estimation unit 204 determines which group a consumer belongs to, on the basis of the consumer's consumption pattern of the first energy. After a consumer's group is determined, the coefficient α of the group is acquired from the coefficient table 210, and the gas usage of a consumer is calculated using Expression (1).

In the present example embodiment, consumers are grouped on the basis of the consumption pattern of the first energy, but there is no limitation thereto. Consumers may be grouped on the basis of a combination of the consumption pattern of the second energy or the consumption patterns of the first energy and the second energy. In the consumption pattern of the second energy, an actual measurement value may be used in a case where the actual measurement value is obtained, a value estimated by the second-energy consumption estimation unit 204 may be used, and the actual measurement value and the estimation value may be combined.

<Change Based on Attribute of Consumer>

The second-energy consumption estimation unit 204 changes the coefficient α on the basis of information indicating a consumer's attribute of the first energy and the second energy.

For example, the second-energy consumption estimation unit 204 increases the coefficient α and increases the ratio of the estimated second energy consumption (the estimated gas usage) to the first energy consumption (the electric power consumption) as the number of persons constituting a family becomes larger.

The information processing apparatus 200 causes a consumer to perform a procedure of user registration before use of service starts or the like, and registers a user's information at the time of the user registration. Specifically, a consumer is caused to perform input of various types of information on a predetermined web site or a user registration screen of an application which are provided by the present service. The information processing apparatus 200 acquires information which is input on the user registration screen by a consumer, and stores the acquired information in a user information storage unit 220.

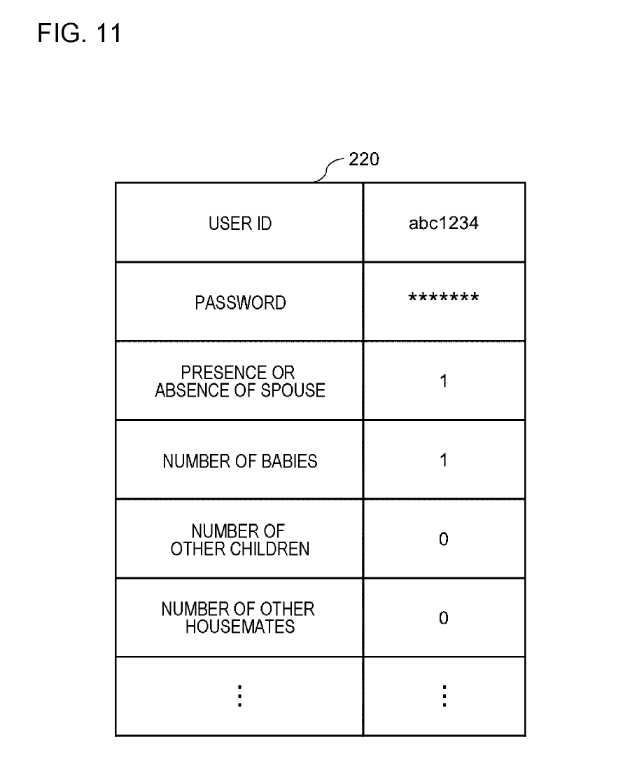

FIG. 11 is a diagram illustrating an example of a data structure of the user information storage unit 220 of the information processing apparatus 200 of the present example embodiment.

The user information storage unit 220 stores, for example, a user ID, a password, and information of the make-up of a family. Examples of the information of the make-up of a family to be exemplified include pieces of information of the presence or absence of a spouse, the presence or absence of a baby, the presence or absence of other housemates, and the like.

The coefficient α may be changed on the basis of these pieces of user's information.

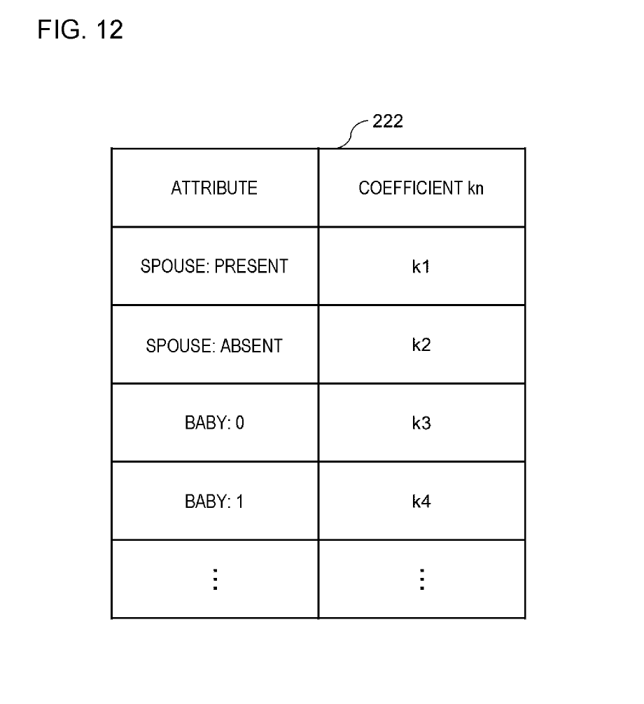

FIG. 12 is a diagram illustrating an example of a coefficient table 222 of the information processing apparatus 200 of the present example embodiment.

Predetermined coefficients kn (n is a natural number) are set for each consumer's attribute information. In the example of FIG. 12, for example, coefficients k1 and k2 are set in accordance with the presence or absence of a spouse, coefficients k3, k4 and the like are set in accordance with the number of babies. Further, although not shown in the drawing, coefficients k5, k6 and the like may be set in accordance with the number of other children, and coefficients k7, k8 and the like may be set in accordance with the number of other housemates. Here, each of the coefficients kn is, for example, a real number of 0 to 1, but a real number equal to or greater than 1 may also be set without being limited thereto. In this manner, it is possible to increase the ratio of the estimated gas usage to the electric power consumption as the number of persons constituting a family becomes larger.

For example, the coefficients may be values for performing weighting, for example, the coefficient k2 in a case where there is no spouse may be 0, and the coefficient k1 in a case where there is a spouse may be 0.05. The coefficients may be values for performing weighting, for example, the coefficient k3 in a case where there are no babies may be 0, and the coefficient k4 in a case where there is one baby may be 0.1. Further, in a case where there are two babies, a value obtained by multiplying the coefficient k4 by two may be used, or a value for performing weighting of 0.15 or the like as a separate coefficient ki (i is a natural number) may be used.

In this example, it is assumed that the coefficient α is obtained by adding the coefficient of an attribute of which a consumer is true. For example, a coefficient kn according to the attribute of a consumer may be added to the coefficient α determined from the aforementioned consumer's consumption pattern, and thereby the consumer's coefficient α may be obtained. In a case where this consumer belongs to a group C and has attributes of FIG. 12, the coefficient α is set to 1.0 (coefficient α of the group C)+0.05 (k1: spouse present)+0.1 (k4: one baby)=1.15.

In this example, each of the coefficients k is added, but there is no limitation thereto. A configuration may be used in which each of the coefficients k is multiplied to obtain the coefficient α, or addition and multiplication may be combined. The coefficient α set for each combination of attributes may be held in a table, and the coefficient α may be acquired by referring to the table.

<Change Based on Attribute of Building>

The second-energy consumption estimation unit 204 changes the coefficient α on the basis of information indicating the attribute of a consumer's building.

The attribute of the building indicates a region of the building or use or non-use of an electric or gas facility in the building. The attribute of an electric or gas facility includes the presence or absence of at least one of an all-electric housing system, an air conditioner, a gas water heater, a bathtub, a shower, an electric water heater, hot-water-type gas floor heater, a gas fan heater, and hot-water-type electric floor heater is further included.

Regarding these facilities or devices, it is preferable that those mainly consuming the first energy and those mainly consuming the second energy are included in the attributes.

In a case where facilities or devices that mainly consume the first energy are included, the second energy consumption becomes smaller than the first energy consumption. Therefore, a change is performed so that the relation of coefficient α<1 is established.

In a case where facilities or devices that mainly consume the second energy are included, the second energy consumption becomes larger than the first energy consumption. Therefore, a change is performed so that the relation of coefficient α>1 is established.

In order to change the coefficient α, a coefficient hn (n is a natural number) is set for each attribute.

For example, the second-energy consumption estimation unit 204 increases the coefficient α and increases the ratio of the estimated gas usage to the electric power consumption as the use frequency of a gas device becomes higher or the number of gas devices becomes larger with respect to the use frequency of an electric device or the number of electric devices.

The information processing apparatus 200 causes a consumer to perform the registration of information relating to the attribute of a building during the aforementioned user registration or at any timing after the registration. Specifically, a consumer is caused to perform input of various types of information on a predetermined web site or a user registration screen of an application which are provided by the present service. The information processing apparatus 200 acquires information which is input on the user information registration screen by a consumer, and stores the acquired information in a facility information storage unit 230.

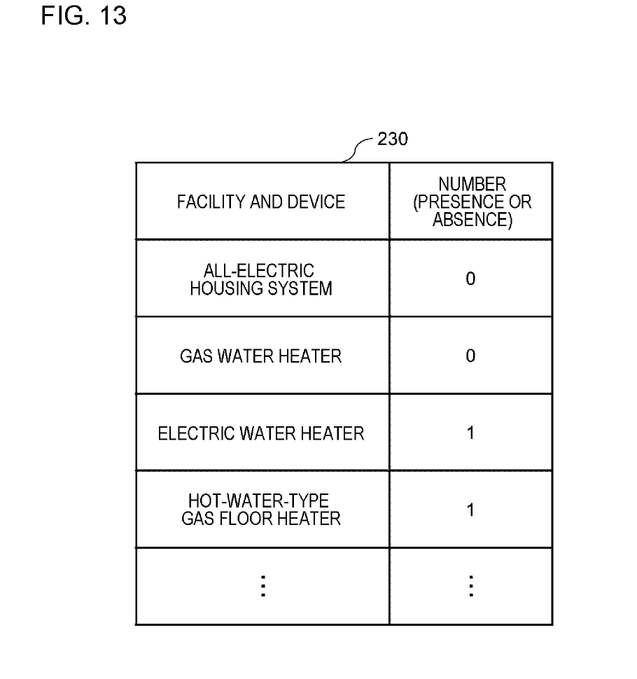

FIG. 13 is a diagram illustrating an example of a data structure of the facility information storage unit 230 of the information processing apparatus 200 of the present example embodiment.

The facility information storage unit 230 stores attribute information of a consumer's building (not shown) in association with the consumer's user ID. The attribute of a building includes, for example, at least one of information of the presence or absence of facilities or devices or the number thereof and information relating to the use frequency of electric devices or facilities.

A description of a configuration in which the information of facilities or devices is registered by a consumer has been given, but there is no limitation thereto. When user registration of facilities or devices is performed in a manufacturer or a sales shop in which the facilities or devices are purchased by a consumer, a configuration may be used in which the information thereof is provided to the information processing apparatus 200 after the consumer's consent is obtained.

Model number information of a facility or device is not essential, but information of the energy consumption of the facility or device can be acquired using the model number from a manufacturer, a sales shop or the like, and thus may be included in the facility information storage unit 230. Further, the facility information storage unit 230 may store the information of the energy consumption of the facility or device which is acquired using the model number.

The information relating to the use frequency of electric devices or facilities may be acquired, for example, by the HEMS 40 of a consumer acquiring operating information of the devices or facilities together with time information, and transmitting the information to the information processing apparatus 100.

The information processing apparatus 100 may further include an operating information acquisition unit (not shown) that acquires operating information together with time information from the HEMS 40 and stores the operating information and the time information in the information storage unit 110, and a calculation unit (not shown) that calculates the use frequency of a device from the operating information and the time information of the device acquired by the operating information acquisition unit. The calculation unit may further use history information of the electric power consumption which is acquired by the first-energy consumption acquisition unit 102.

The operating information of a device is, for example, information indicating the operating situation such as operation/stop/standby of a device.

Further, the attribute of a building may include information of the number of devices such as an air conditioner or a sitting room in which each device is installed. This is because the energy consumption pattern changes depending on the type of sitting room, and can be thus reflected in coefficients. For example, between an air conditioner installed in a living room and an air conditioner installed in a bedroom, use times, setting temperatures and the like are different from each other. These pieces of information may be registered by a consumer, and may be acquired from house builders, house sellers, builder's offices and the like after a consumer's consent is obtained.

The coefficient α is changed on the basis of the attribute of a facility or a device.

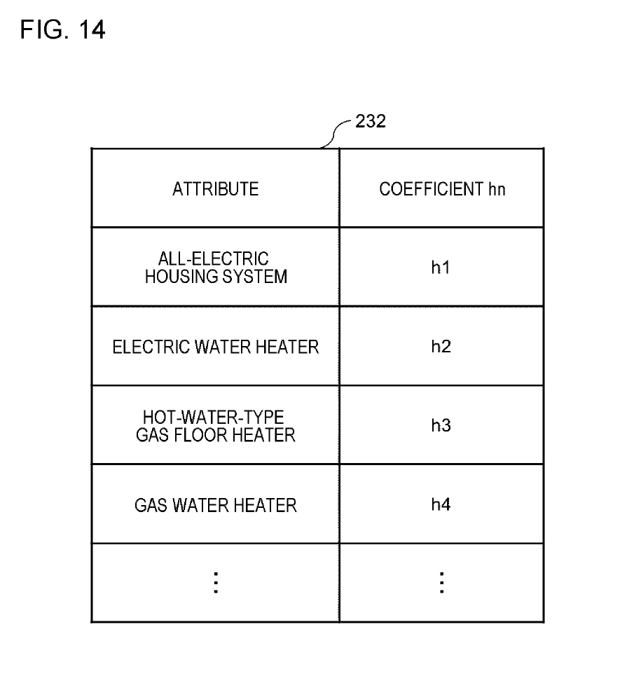

FIG. 14 is a diagram illustrating an example of a coefficient table 232 of the information processing apparatus 200 of the present example embodiment.

Coefficients hn (n is a natural number) are set for each consumer's attribute information. In the example of FIG. 14, for example, the coefficient hn added or multiplied in a case of being possessed by a consumer is set for each facility or device. The value of the coefficient hn may be further added or multiplied for each of the number of facilities or devices. Here, each of the coefficients hn is, for example, a real number of 0 to 1, but a real number equal to or greater than 1 may also be set without being limited thereto.

In addition, in a case where the attribute of a consumer's building is an all-electric housing system in the facility information storage unit 230 of FIG. 13, gas is not used. Therefore, in a case where the second energy is gas, the estimation process of the second-energy consumption estimation unit 104 is not performed on the gas usage. This does not apply to a case where the second energy is energy other than gas, for example, a case where the second energy is kerosene or the like, and the estimation process of the kerosene consumption may be performed without being limited thereto.

In this example, it is assumed that the coefficient α is obtained by adding the coefficient hn of an attribute of which a consumer is true. For example, in the example of FIG. 13, the attributes of a consumer's building have an electric water heater and hot-water-type gas floor heater. Consequently, the coefficient α of the consumer may be obtained by adding the coefficients h2 (for example, 0.05) and h3 (for example, 0.5) corresponding to the attributes of the building and further multiplying the above-described coefficient α determined from the consumer's consumption pattern by a coefficient obtained by the addition. In a case where this consumer belongs to the group C and has attributes of FIG. 13, the coefficient α is set to 1.0 (coefficient α of the group C)×(0.05 (h2: electric water heater present)+0.5 (h3: hot-water-type gas floor heater present))=0.55.

In this example, each of the coefficients hn is added and the coefficient α is multiplied by the added coefficient, but there is no limitation thereto. A configuration may be used in which the coefficient α is obtained by multiplying each of the coefficients hn together, or addition, multiplication, subtraction, and division may be combined. The coefficient α set for each combination of attributes may be held in a table, and the coefficient α may be acquired by referring to the table.

In addition, information of a region of the attribute of a building may be acquired using at least any one method of the following. The acquired information of a region is stored in the information storage unit 110.

(b1) Input of a consumer's address is accepted during user information registration, and the consumer's region information is registered on the basis of the input address information.

(b2) Region information of a consumer's residence is acquired on the basis of identification information of the smart meter 10 after the consumer's consent is obtained through the electric power company 20.

(b3) Location information (region) is registered by accessing a predetermined web site or starting up an application using a consumer's portable terminal and opening the consumer's region information registration screen. Specifically, location information is acquired using a global positioning system (GPS) function of the portable terminal in accordance with the operation of the registration screen when a consumer is in his or her residence, and a region is identified and registered from the acquired location information.

The coefficient α (or coefficient hi) is defined for each region, and is stored in a coefficient table (not shown). The second-energy consumption estimation unit 204 refers to this coefficient table, acquires the coefficient α corresponding to a consumer's region information, and uses the acquired coefficient in the estimation of the second energy consumption. For example, the coefficient α may be obtained by a combination (multiplication, addition, subtraction, and division) of the coefficient hi obtained from the region information and the coefficient hn obtained from the above-described information of facilities or devices.

<Change Based on Time>

The second-energy consumption estimation unit 204 changes the coefficient α based on time information.

As the time information, time information associated with the first energy consumption may be used.

The coefficient α is set according to a time slot, a day of the week, a date, a month, and the like, and may be stored in a coefficient table.

The coefficient α may be obtained by combining (multiplying or adding) a plurality of coefficients j1 to jm (m is a natural number) having different units, and the coefficient α may be set by a combination of different units and be stored in a coefficient table.

The second-energy consumption estimation unit 204 acquires a coefficient corresponding to the time information associated with the first energy consumption from the coefficient table, and uses the acquired coefficient in the estimation of the second energy consumption.

As described above, the coefficient α based on a consumer's consumption pattern may be determined on the basis of at least any of the information of the consumer's attribute and the attribute of a building.

In addition, the second-energy consumption estimation unit 204 may change the coefficient α and the coefficient β using a matrix table indicating a combination of the coefficient α and the coefficient β.

In addition, the consumer's attribute includes any of an individual, an autonomous body, a company, and the business type of the company to which the consumer of the first energy and the second energy corresponds.

Since a correlation between consumptions of the first energy and the second energy is different depending on this attribute, the coefficient α according to each attribute is set, and is stored in the information storage unit 110. The information processing apparatus 200 may input the consumer's attribute on the above-described user information registration screen or the like, and register the input attribute in the information storage unit 110. The second-energy consumption estimation unit 204 may refer to the consumer's attribute, acquire the coefficient α corresponding to the attribute, and estimate the second energy consumption on the basis of the first energy consumption, the coefficient α, and the coefficient β.

In the information processing apparatus 200 of the present example embodiment, the accumulated value of the first energy consumption over a predetermined period is acquired by the second-energy consumption estimation unit 204. The second energy consumption is then calculated by the second-energy consumption estimation unit 204 in accordance with Expression (1) on the basis of the accumulated first energy consumption. The coefficient α may be changed on the basis of various types of information such as a consumer's attribute and the attribute of a building.

In this manner, according to information processing apparatus 200 of the present example embodiment, since the coefficient α used in the estimation of the second energy consumption can be changed in accordance with the conditions of a consumer's attribute and the like, the second energy consumption can be estimated with high accuracy on the basis of conditions in conformity with real substance.

In addition, the information or the like of the attribute of a consumer or a building can be acquired by a simple registration operation at the time of user registration during service use, or the like. Since a coefficient can be selected using a coefficient table or the like, it is also possible to reduce a load of arithmetic processing of the second-energy consumption estimation unit 204.

### Fourth Example Embodiment

Next, an information processing apparatus 300 according to a fourth example embodiment of the present invention will be described below.

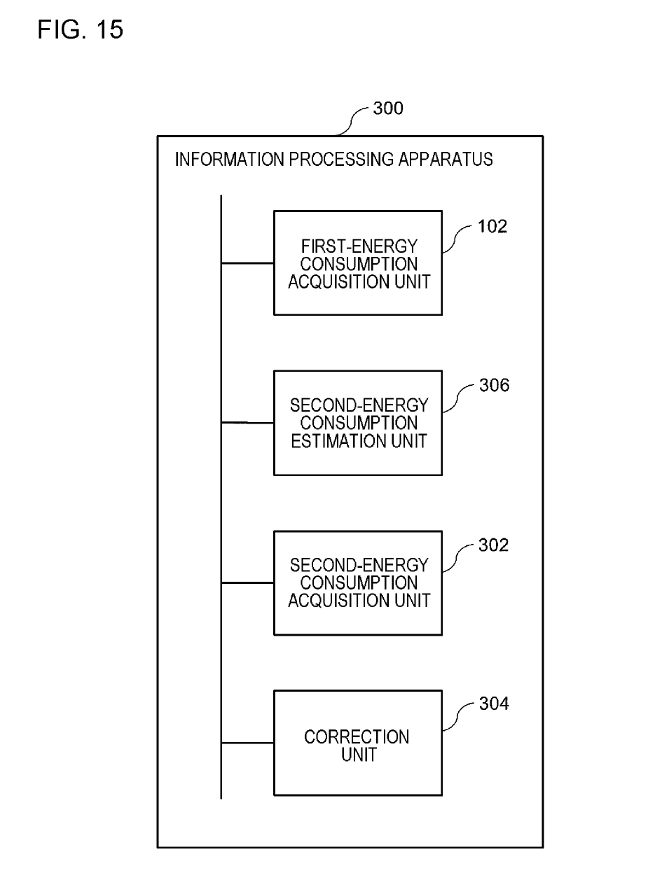

FIG. 15 is a functional block diagram illustrating a logical configuration of the information processing apparatus 300 according to the example embodiment of the present invention.

The information processing apparatus 300 of the present example embodiment is different from the information processing apparatus 100 and the information processing apparatus 200 of the above example embodiments, in that this information processing apparatus has a configuration in which the estimated second energy consumption is corrected using the actual second energy consumption, and the value of the corrected second energy consumption is used in subsequent estimation.

The information processing apparatus 300 of the present example embodiment includes the first-energy consumption acquisition unit 102, a second-energy consumption acquisition unit 302, a correction unit 304, and a second-energy consumption estimation unit 306.

The first-energy consumption acquisition unit 102 is the same as that of the information processing apparatus 100 or the information processing apparatus 200 of the above example embodiments.

The second-energy consumption acquisition unit 302 acquires the actual second energy consumption.

The correction unit 304 corrects the second energy consumption which is estimated by the second-energy consumption estimation unit 306, on the basis of the actual second energy consumption which is acquired by the second-energy consumption acquisition unit 302.

The second-energy consumption estimation unit 306 has the same function as that of the second-energy consumption estimation unit 104 or the second-energy consumption estimation unit 204 of the above example embodiments, and further performs subsequent estimation by using the value of the second energy consumption after correction.

The actual second energy consumption may be acquired by a worker performing meter reading, for example, when the gas cylinder 32 is replaced. The actual amount may be acquired by a worker visually reading the value of the meter and manually inputting the value to a handy terminal or the like. Alternatively, worker may use a near field communication function or the like of the handy terminal to perform communication with the meter and acquire a meter-reading value from the meter.

The meter-reading value is transmitted from the handy terminal to the LP gas company 30 or the information processing apparatus 300 which is a provider's server. The second-energy consumption acquisition unit 302 receives the meter-reading value of the meter from the handy terminal.

The correction unit 304 replaces the latest second energy consumption (the gas usage) which is estimated by the second-energy consumption estimation unit 306 with the actual value of the second energy consumption.

In the present example embodiment, the information processing apparatus 300 stores a meter-reading value M1 acquired at the time of the last meter reading, a capacity L of the gas cylinder 32, and a meter-reading value M2 acquired at the time of the current meter reading in the information storage unit 110. The last and current meter-reading values may be updated to up-to-date information and held at all times, and all the meter-reading values may be held as history information together with date and time information.

When the second-energy consumption acquisition unit 302 acquires the latest meter-reading value of the gas cylinder 32 from the handy terminal, the correction unit 304 first rewrites and updates the meter-reading value M1 with the meter-reading value M2. The correction unit 304 then updates the meter-reading value M2 with the acquired latest meter-reading value.

The correction unit 304 calculates the actual second energy consumption, on the basis of the last meter-reading value M1, the capacity L of the gas cylinder 32, and the current meter-reading value M2.

Actual gas usage=M1+L−M2 Expression (2)

The correction unit 304 updates the second energy consumption (the gas usage) which is estimated by the second-energy consumption estimation unit 306 with the actual gas usage which is calculated in Expression (2).

The second-energy consumption estimation unit 306 performs estimation after update, using the second energy consumption which is corrected by the correction unit 304 when the gas usage is estimated. In a case where a process of totalizing the gas usage is continued even after a correction process is executed in the middle of a period for estimation, this correction process is especially useful.

The second-energy consumption estimation unit 306 may change the coefficient α on the basis of the correction value of the second energy consumption in the correction unit 304.

The total first energy consumption, the coefficient β, and the actual second energy consumption are substituted into Expression (1) to obtain α, and the obtained value is set to a coefficient α′. This coefficient α′ is a value to be intrinsically used because the actual second energy consumption is obtained from the first energy consumption.

Therefore, the second-energy consumption estimation unit 306 may use this coefficient α′ as the subsequent coefficient α.

However, since it is considered that even a temporary error is present, a value obtained by performing any weighting may be obtained, and the value may be replaced by the coefficient α.

Coefficient α=coefficient α up to the last×w+current coefficient α′×(1−w) Expression (3)

Here, w is a weighting coefficient, and the relation of 0<w<1 is established.

As w decreases, the ratio of the current coefficient α′ obtained from the actual measurement value becomes larger. That is, correction approximate to an actual value is performed. In a case where w is 0.5, the coefficient α is set to be an average of the last and current values.

In addition, w may be a constant, but preferably be changed depending on the magnitude of an error between the estimated second energy consumption and the actual second energy consumption.

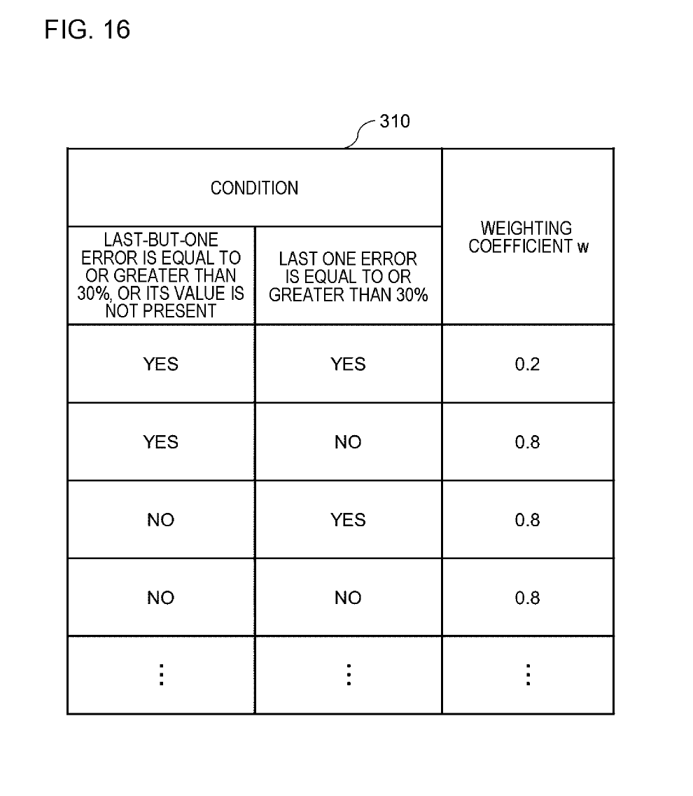

FIG. 16 is a diagram illustrating an example of a setting condition matrix table of a weighting coefficient w of the coefficient α of the information processing apparatus 300 according to the present example embodiment.

A setting condition matrix table 310 has the value of w set therein using a change in an error between the estimation value and the actual measurement value of the second energy consumption as a condition.

In this example, in a case where the error is continuously large, w is set so as to perform correction of the coefficient α approximate to the coefficient α′. Thereby, the coefficient α is changed greatly. On the other hand, in a case where the error temporarily large rather than continuously large, w is set so that the coefficient α is not changed greatly. In this manner, it is possible to avoid excessive correction due to a temporary increase or decrease in gas usage.

A case where the value of the last-but-one error is not present is, for example, an initial installation time of the gas cylinder 32.

The correction of the coefficient α may be performed for each consumer.

The above-described correction process adopts a method simplified so as to reduce an information processing load of the information processing apparatus 300, but there is no limitation thereto, and a correction process may be performed using other learning methods.

In the present example embodiment, the actual second energy consumption is acquired by the second-energy consumption acquisition unit 302. The estimation value of the second energy consumption is corrected to an actual value by the correction unit 304. The subsequent process is performed using the corrected second energy consumption by the second-energy consumption estimation unit 306.

In this manner, according to the information processing apparatus 300 of the present example embodiment, it is possible to correct the estimation value to an actual value, and to improve the accuracy of the estimation value.

In addition, since the coefficient α is changed depending on an error, it is possible to reflect an actual value in the subsequent estimation process.

Further, since the correction of the coefficient α according to an error is changed with any weighting coefficient w, it is possible to appropriately control the degree of reflecting an error. Further, since the setting of the weighting coefficient w can also be changed using predetermined conditions, it is possible for the coefficient α not to be immediately changed in a case where an error increases temporarily.

Hereinbefore, although the example embodiments of the present invention have been set forth with reference to the accompanying drawings, the example embodiments are merely illustrative of the present invention, and various configurations other than those stated above can be adopted.

For example, in the above example embodiments, a description has been given of a configuration in which the second energy consumption is estimated on the basis of the first energy consumption. However, the present invention can also be applied to a configuration in which an energy consumption such as gas or power is estimated on the basis of water usage, instead of an energy consumption, or a configuration in which water usage is estimated on the basis of an energy consumption such as gas or power.

Hereinbefore, the present invention has been described with reference to the example embodiments and the examples, but the present invention is not limited to the example embodiments and the examples described above. In the configurations and the details of the present invention, various modifications as can be understood by those skilled in the art may be made without departing from the scope of the present invention.

It should be noted that, in a case where information relating to a user is acquired and used in the present invention, this is assumed to be duly performed.

Some or all of the example embodiments may be described as in the following additions, but there is no limitation thereto.

1. An information processing apparatus including:

a first-energy consumption acquisition unit that acquires a first energy consumption of a consumer; and

a second-energy consumption estimation unit that estimates a second energy consumption of the consumer, using the first energy consumption.

2. The information processing apparatus according to 1,

wherein the first energy is electric power, and the second energy is gas.

3. The information processing apparatus according to 1 or 2, wherein the second-energy consumption estimation unit estimates the second energy consumption whenever the first energy consumption is acquired from an electric energy meter.

4. The information processing apparatus according to 1 or 2,

wherein the second-energy consumption estimation unit estimates the second energy consumption, on the basis of an integration value of the first energy consumption which is acquired from an electric energy meter.

5. The information processing apparatus according to 1 or 2,

wherein the second-energy consumption estimation unit estimates the second energy consumption, on the basis of a time-series variation in the integration value of the first energy consumption which is acquired from an electric energy meter.

6. The information processing apparatus according to any one of 1 to 5, further including a notification unit that gives notice of a time to replace a container for containing the second energy, the time being set on the basis of a history of the second energy consumption estimated by the second-energy consumption estimation unit and a capacity of the container.

7. The information processing apparatus according to any one of 1 to 6,

wherein the second-energy consumption estimation unit further changes a coefficient α indicating a correlation between the first energy consumption and the second energy consumption, on the basis of information relating to weather.

8. The information processing apparatus according to 7,

wherein the second-energy consumption estimation unit acquires an accumulated value of the first energy consumption consumed over a predetermined period, and calculates the second energy consumption, in accordance with the following Expression (1), on the basis of the acquired accumulated first energy consumption:

second energy consumption=accumulated first energy consumption×α×β Expression (1)

wherein, in the Expression (1), α is a coefficient indicating a correlation between the first energy and the second energy, and β is a coefficient based on the information relating to weather.

9. The information processing apparatus according to 8,

wherein the second-energy consumption estimation unit changes the coefficient α using a table indicating a relationship between the coefficient α and the coefficient β.

10. The information processing apparatus according to any one of 7 to 9,

wherein the second-energy consumption estimation unit changes the coefficient α on the basis of a consumption pattern of the first energy.

11. The information processing apparatus according to any one of 7 to 10, wherein the second-energy consumption estimation unit further changes the coefficient α on the basis of information indicating a consumer's attribute of the first energy and the second energy.

12. The information processing apparatus according to 11, wherein the second-energy consumption estimation unit increases the coefficient α and increases a ratio of the estimated second energy consumption to the first energy consumption as the number of persons constituting a family becomes larger.

13. The information processing apparatus according to 11 or 12,

wherein the consumer's attribute includes any of an individual, an autonomous body, a company, and a business type of the company to which the consumer of the first energy and the second energy corresponds.

14. The information processing apparatus according to any one of 7 to 13,

wherein the second-energy consumption estimation unit further changes the coefficient α on the basis of information indicating an attribute of the consumer's building.

15. The information processing apparatus according to 14,

wherein the second-energy consumption estimation unit increases the coefficient α and increases a ratio of estimated gas usage to an electric power consumption as use frequency of a gas device becomes higher or the number of gas devices becomes larger with respect to use frequency of an electric device or the number of electric devices.

16. The information processing apparatus according to 14 or 15,

wherein the attribute of the building indicates a region of the building or use or non-use of an electric or gas facility in the building, and

an attribute of the electric or gas facility includes the presence or absence of at least one of an all-electric housing system, an air conditioner, a gas water heater, a bathtub, a shower, an electric water heater, hot-water-type gas floor heater, a gas fan heater, and hot-water-type electric floor heater is further included.

17. The information processing apparatus according to any one of 7 to 16,

wherein the second-energy consumption estimation unit further changes the coefficient α based on time information.

18. The information processing apparatus according to any one of 1 to 17, further including:

a second-energy consumption acquisition unit that acquires an actual second energy consumption; and

a correction unit that corrects the second energy consumption which is estimated by the second-energy consumption estimation unit, on the basis of the actual second energy consumption which is acquired by the second-energy consumption acquisition unit,

wherein the second-energy consumption estimation unit performs subsequent estimation by using a value of the second energy consumption after correction.

19. The information processing apparatus according to 18,

wherein the second-energy consumption estimation unit changes the coefficient α on the basis of a correction value of the second energy consumption in the correction unit.

20. An information processing method performed by an information processing apparatus, the method including:

acquiring a first energy consumption of a consumer; and

estimating a second energy consumption of the consumer, using the first energy consumption.

21. The information processing method according to 20,

wherein the first energy is electric power, and the second energy is gas.

22. The information processing method according to 20 or 21, the method being performed by the information processing apparatus, the method including estimating the second energy consumption whenever the first energy consumption is acquired from an electric energy meter.

23. The information processing method according to 20 or 21, the method being performed by the information processing apparatus, the method including estimating the second energy consumption, on the basis of an integration value of the first energy consumption which is acquired from an electric energy meter.

24. The information processing method according to 20 or 21, the method being performed by the information processing apparatus, the method including estimating the second energy consumption, on the basis of a time-series variation in an integration value of the first energy consumption which is acquired from an electric energy meter.

25. The information processing method according to any one of 20 to 24, the method being performed by the information processing apparatus, the method further including giving notice of a time to replace a container for containing the second energy, the time being set on the basis of a history of the estimated second energy consumption and a capacity of the container.

26. The information processing method according to any one of 20 to 25, the method being performed by the information processing apparatus, the method including further changing a coefficient α indicating a correlation between the first energy consumption and the second energy consumption, on the basis of information relating to weather.

27. The information processing method according to 26, the method being performed by the information processing apparatus, the method including acquiring an accumulated value of the first energy consumption consumed over a predetermined period, and calculate the second energy consumption, in accordance with the following Expression (1), on the basis of the acquired accumulated first energy consumption:

second energy consumption=accumulated first energy consumption×α×β Expression (1)

wherein, in the Expression (1), α is a coefficient indicating a correlation between the first energy and the second energy, and β is a coefficient based on the information relating to weather.

28. The information processing method according to 27, the method being performed by the information processing apparatus, the method including changing the coefficient α using a table indicating a relationship between the coefficient α and the coefficient β.

29. The information processing method according to any one of 26 to 28, the method being performed by the information processing apparatus, the method including changing the coefficient α on the basis of a consumption pattern of the first energy.

30. The information processing method according to any one of 26 to 29, the method being performed by the information processing apparatus, the method including further changing the coefficient α on the basis of information indicating an attribute of a consumer of the first energy and the second energy.

31. The information processing method according to 30, the method being performed by the information processing apparatus, the method including increasing the coefficient α and increasing a ratio of the estimated second energy consumption to the first energy consumption as the number of persons constituting a family becomes larger.

32. The information processing method according to 30 or 31,

wherein the consumer's attribute includes any of an individual, an autonomous body, a company, and a business type of the company to which the consumer of the first energy and the second energy corresponds.

33. The information processing method according to any one of 26 to 32, the method being performed by the information processing apparatus, the method including further changing the coefficient α on the basis of information indicating an attribute of the consumer's building.

34. The information processing method according to 33, the method being performed by the information processing apparatus, the method including increasing the coefficient α and increasing a ratio of estimated gas usage to an electric power consumption as use frequency of a gas device becomes higher or the number of gas devices becomes larger with respect to use frequency of an electric device or the number of electric devices.

35. The information processing method according to 33 or 34,

wherein the attribute of the building indicates a region of the building or use or non-use of an electric or gas facility in the building, and

an attribute of the electric or gas facility includes the presence or absence of at least one of an all-electric housing system, an air conditioner, a gas water heater, a bathtub, a shower, an electric water heater, hot-water-type gas floor heater, a gas fan heater, and hot-water-type electric floor heater is further included.

36. The information processing method according to any one of 26 to 35, the method being performed by the information processing apparatus, the method including further changing the coefficient α based on time information.

37. The information processing method according to any one of 20 to 36, the method being performed by the information processing apparatus, the method including:

acquiring an actual second energy consumption;

correcting the estimated second energy consumption, on the basis of the acquired actual second energy consumption; and

performing subsequent estimation by using a value of the second energy consumption after correction.

38. The information processing method according to 37, the method being performed by the information processing apparatus, the method including changing the coefficient α on the basis of a correction value of the second energy consumption when the correction is performed.

39. A program for causing a computer to execute:

a procedure of acquiring a first energy consumption of a consumer; and

a procedure of estimating a second energy consumption of the consumer, using the first energy consumption.

40. The program according to 39,

wherein the first energy is electric power, and the second energy is gas.

41. The program according to 39 or 40,

wherein in the procedure of estimating a second energy consumption, the program causes a computer to execute a procedure of estimating the second energy consumption whenever the first energy consumption is acquired from an electric energy meter.

42. The program according to 39 or 40,

wherein in the procedure of estimating a second energy consumption, the program causes a computer to execute a procedure of estimating the second energy consumption, on the basis of an integration value of the first energy consumption which is acquired from an electric energy meter.

43. The program according to 39 or 40,

wherein in the procedure of estimating a second energy consumption, the program causes a computer to execute a procedure of estimating the second energy consumption, on the basis of a time-series variation in an integration value of the first energy consumption which is acquired from an electric energy meter.

44. The program according to any one of 39 to 43, further causing a computer to execute a procedure of giving notice of a time to replace a container for containing the second energy, the time being set on the basis of a history of the estimated second energy consumption and a capacity of the container.

45. The program according to any one of 39 to 44,

wherein in the procedure of estimating a second energy consumption, the program causes a computer to execute a procedure of further changing a coefficient α indicating a correlation between the first energy consumption and the second energy consumption, on the basis of information relating to weather.

46. The program according to 45,

wherein in the procedure of estimating a second energy consumption, the program causes a computer to execute a procedure of acquiring an accumulated value of the first energy consumption consumed over a predetermined period, and calculating the second energy consumption, in accordance with the following Expression (1), on the basis of the acquired accumulated first energy consumption:

second energy consumption=accumulated first energy consumption×α×β Expression (1)

wherein, in the Expression (1), α is a coefficient indicating a correlation between the first energy and the second energy, and β is a coefficient based on the information relating to weather.

47. The program according to 46,

wherein in the procedure of estimating a second energy consumption, the program further causes a computer to execute a procedure of changing the coefficient α using a table indicating a relationship between the coefficient α and the coefficient β.

48. The program according to any one of 45 to 47,

wherein in the procedure of estimating a second energy consumption, the program further causes a computer to execute a procedure of changing the coefficient α on the basis of a consumption pattern of the first energy.

49. The program according to any one of 45 to 48,

wherein in the procedure of estimating a second energy consumption, the program causes a computer to execute a procedure of further changing the coefficient α on the basis of information indicating an attribute of a consumer of the first energy and the second energy.

50. The program according to 49,

wherein in the procedure of estimating a second energy consumption, the program further causes a computer to execute a procedure of increasing the coefficient α and increasing a ratio of the estimated second energy consumption to the first energy consumption as the number of persons constituting a family becomes larger.

51. The program according to 49 or 50,

wherein the consumer's attribute includes any of an individual, an autonomous body, a company, and a business type of the company to which the consumer of the first energy and the second energy corresponds.

52. The program according to any one of 45 to 51,

wherein in the procedure of estimating a second energy consumption, the program causes a computer to execute a procedure of further changing the coefficient α on the basis of information indicating an attribute of the consumer's building.

53. The program according to 52,

wherein in the procedure of estimating a second energy consumption, the program further causes a computer to execute a procedure of increasing the coefficient α as use frequency of a gas device becomes higher or the number of gas devices becomes larger with respect to use frequency of an electric device or the number of electric devices, and increasing a ratio of estimated gas usage to an electric power consumption.

54. The program according to 52 or 53,

wherein the attribute of the building indicates a region of the building or use or non-use of an electric or gas facility in the building, and

an attribute of the electric or gas facility includes the presence or absence of at least one of an all-electric housing system, an air conditioner, a gas water heater, a bathtub, a shower, an electric water heater, hot-water-type gas floor heater, a gas fan heater, and hot-water-type electric floor heater is further included.

55. The program according to any one of 45 to 54,

wherein in the procedure of estimating a second energy consumption, the program causes a computer to execute a procedure of further changing the coefficient α based on time information.

56. The program according to any one of 39 to 55, further causing a computer to execute:

a procedure of acquiring an actual second energy consumption; and

a procedure of correcting the estimated second energy consumption, on the basis of the acquired actual second energy consumption,

wherein in the procedure of estimating a second energy consumption, the program further causes a computer to execute a procedure of performing subsequent estimation by using a value of the second energy consumption after correction.

57. The program according to 56,

wherein in the procedure of estimating a second energy consumption, the program further causes a computer to execute a procedure of changing the coefficient α on the basis of a correction value of the second energy consumption in the procedure of correcting the consumption.

This application is based on Japanese Patent Application No. 2015-243493 filed on Dec. 14, 2015, the content of which is incorporated hereinto by reference.

What is claimed is:

1. An information processing apparatus comprising:
a first-energy consumption acquisition unit that acquires a first energy consumption of a consumer; and
a second-energy consumption estimation unit that estimates a second energy consumption of the consumer, using the first energy consumption.

2. The information processing apparatus according to claim 1,
wherein the first energy is electric power, and the second energy is gas.

3. The information processing apparatus according to claim 1,
wherein the second-energy consumption estimation unit estimates the second energy consumption whenever the first energy consumption is acquired from an electric energy meter.

4. The information processing apparatus according to claim 1,
wherein the second-energy consumption estimation unit estimates the second energy consumption, on the basis of an integration value of the first energy consumption which is acquired from an electric energy meter.

5. The information processing apparatus according to claim 1,
wherein the second-energy consumption estimation unit estimates the second energy consumption, on the basis of a time-series variation in an integration value of the first energy consumption which is acquired from an electric energy meter.

6. The information processing apparatus according to claim 1, further comprising a notification unit that gives notice of a time to replace a container for containing the second energy, the time being set on the basis of a history of the second energy consumption estimated by the second-energy consumption estimation unit and a capacity of the container.

7. The information processing apparatus according to claim 1,
wherein the second-energy consumption estimation unit further changes a coefficient α indicating a correlation between the first energy consumption and the second energy consumption, on the basis of information relating to weather.

8. The information processing apparatus according to claim 7,
wherein the second-energy consumption estimation unit acquires an accumulated value of the first energy consumption consumed over a predetermined period, and calculates the second energy consumption, in accordance with the following Expression (1), on the basis of the acquired accumulated first energy consumption:
second energy consumption=accumulated first energy consumption×α×β Expression (1)
wherein, in the Expression (1), α is a coefficient indicating a correlation between the first energy and the second energy, and β is a coefficient based on the information relating to weather.

9. The information processing apparatus according to claim 8,
wherein the second-energy consumption estimation unit changes the coefficient α using a table indicating a relationship between the coefficient α and the coefficient β.

10. The information processing apparatus according to claim 7,
wherein the second-energy consumption estimation unit changes the coefficient α on the basis of a consumption pattern of the first energy.

11. The information processing apparatus according to claim 7,
wherein the second-energy consumption estimation unit further changes the coefficient α on the basis of information indicating an attribute of a consumer of the first energy and the second energy.

12. The information processing apparatus according to claim 11,
wherein the second-energy consumption estimation unit increases the coefficient α and increases a ratio of the estimated second energy consumption to the first energy consumption as the number of persons constituting a family becomes larger.

13. The information processing apparatus according to claim 11,
wherein the consumer's attribute comprises any of an individual, an autonomous body, a company, and a business type of the company to which the consumer of the first energy and the second energy corresponds.

14. The information processing apparatus according to claim 7,
wherein the second-energy consumption estimation unit further changes the coefficient α on the basis of information indicating an attribute of the consumer's building.

15. The information processing apparatus according to claim 14,
wherein the second-energy consumption estimation unit increases the coefficient α and increases a ratio of estimated gas usage to an electric power consumption as use frequency of a gas device becomes higher or the number of gas devices becomes larger with respect to use frequency of an electric device or the number of electric devices.

16. The information processing apparatus according to claim 14,
wherein the attribute of the building indicates a region of the building or use or non-use of an electric or gas facility in the building, and
an attribute of the electric or gas facility comprises the presence or absence of at least one of an all-electric housing system, an air conditioner, a gas water heater, a bathtub, a shower, an electric water heater, hot-water-type gas floor heater, a gas fan heater, and hot-water-type electric floor heater is further included.

17. The information processing apparatus according to claim 7,
wherein the second-energy consumption estimation unit further changes the coefficient α based on time information.

18. The information processing apparatus according to claim 1, further comprising:
a second-energy consumption acquisition unit that acquires an actual second energy consumption; and
a correction unit that corrects the second energy consumption which is estimated by the second-energy consumption estimation unit, on the basis of the actual second energy consumption which is acquired by the second-energy consumption acquisition unit,
wherein the second-energy consumption estimation unit performs subsequent estimation by using a value of the second energy consumption after correction.

19. The information processing apparatus according to claim 18,
wherein the second-energy consumption estimation unit changes the coefficient α on the basis of a correction value of the second energy consumption in the correction unit.

20. An information processing method performed by an information processing apparatus, the method comprising:
acquiring a first energy consumption of a consumer; and
estimating a second energy consumption of the consumer, using the first energy consumption.

21-57. (canceled)
